(19) United States
(12) Patent Application Publication
(10) Pub. No.: US 2005/0280085 A1
(43) Pub. Date: Dec. 22, 2005

(54) LDMOS transistor having gate shield and trench source capacitor

(75) Inventors: Jeff Babcock, Sunnyvale, CA (US); Johan Agus Darmawan, Cupertino, CA (US); John Mason, Sunnyvale, CA (US)

Correspondence Address: BEYER WEAVER & THOMAS LLP, P.O. BOX 70250, OAKLAND, CA, 94612-0250, US

(73) Assignee: CREE MICROWAVE, INC., Sunnyvale, CA (US)

(21) Appl. No.: 10/870,012

(22) Filed: Jun. 16, 2004

(51) Int. Cl. H01L 29/76

(52) U.S. Cl. 257/341

(57) ABSTRACT

An LDMOS transistor includes a trench source capacitor structure and a gate-drain shield which can be interconnected whereby the source capacitor can be grounded to provide an RF ground for the shield and whereby the RF shield can have a positive DC voltage bias to enhance laterally diffused drain conductance without increasing doping therein. The trench capacitor structure can include one or more adjacent trenches to increase capacitor plate area.

### CROSS-REFERENCE TO RELATED APPLICATIONS

This application is related to co-pending applications CREEP034, CREEP038, and CREEP037, filed concurrently herewith, which are incorporated herein by reference for all purposes.

### BACKGROUND OF THE INVENTION

This invention relates generally to semiconductor transistors, and more particularly the invention relates to laterally diffused MOS (LDMOS) transistors.

The LDMOS transistor is used in RF/microwave power amplifiers. The device is typically fabricated in an epitaxial silicon layer (P−) on a more highly doped silicon substrate (P+). A grounded source configuration is achieved by a deep P+ sinker diffusion from the source region to the P+ substrate, which is grounded. (See, for example, U.S. Pat. No. 5,869,875.)

The gate to drain feedback capacitor (CGD) of any MOSFET device must be minimized in order to maximize RF gain and minimize signal distortion. The gate to drain feedback capacitance is critical since it is effectively multiplied by the voltage gain of the device.

Heretofore, the use of a Faraday shield made of metal or polysilicon formed over the gate structure has been proposed as disclosed in U.S. Pat. No. 5,252,848. (See, also U.S. Pat. No. 6,215,152 for MOSFET HAVING SELF-ALIGNED GATE AND BURIED SHIELD AND METHOD OF MAKING SAME.)

Copending application CREEP038 discloses a LDMOS transistor having a source capacitor and gate shield whereby a plate of the capacitor and the shield can be fabricated using the same metallization step. The source capacitor allows the gate shield to be connected to RF ground through the capacitor while permitting a DC voltage bias on the shield which increases drain conductance without increasing the dopant concentration in the drain, which could adversely affect reverse bias breakdown voltage.

Copending application CREEP037 discloses a LDMOS transistor which is fabricated on a N+ substrate and in a P− epitaxial layer on the substrate. The N doped source is connected to the N+ substrate by a trench contact through the epitaxial layer to the substrate.

The present invention utilizes the source capacitor and shield of CREEP038 with the trench structure of CREEP037 to increase the capacitance of the source capacitor.

### SUMMARY OF THE INVENTION

The present invention provides an LDMOS transistor structure including a source capacitor and gate shield in which the source capacitor is formed in a groove in the substrate and epitaxial layer to thereby increase the surface area of the capacitor plates and thus increase the capacitance of the source capacitor. The one plate of the capacitor and the shield can be fabricated using the same metallization. The substrate can be either P-doped or N-doped. The gate shield can be RF grounded through the source capacitor while a DC voltage is applied to the shield.

The invention, and objects and features thereof, will be more readily apparent from the following detailed description and appended claims when take with the drawings.

### BRIEF DESCRIPTION OF THE DRAWINGS

FIGS. 1A, 1B are a perspective view and a side view in section of two embodiments of a LDMOS transistor in accordance with the invention.

FIGS. 2-22 are section views, illustrating steps in fabricating the LDMOS transistor of FIG. 1.

### DETAILED DESCRIPTION OF ILLUSTRATED EMBODIMENTS

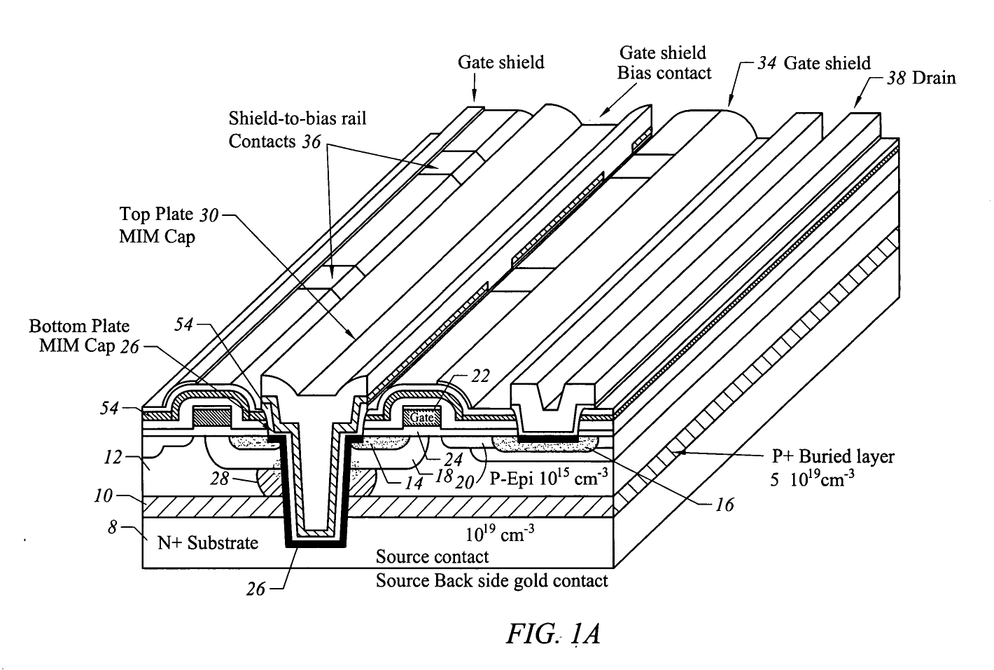

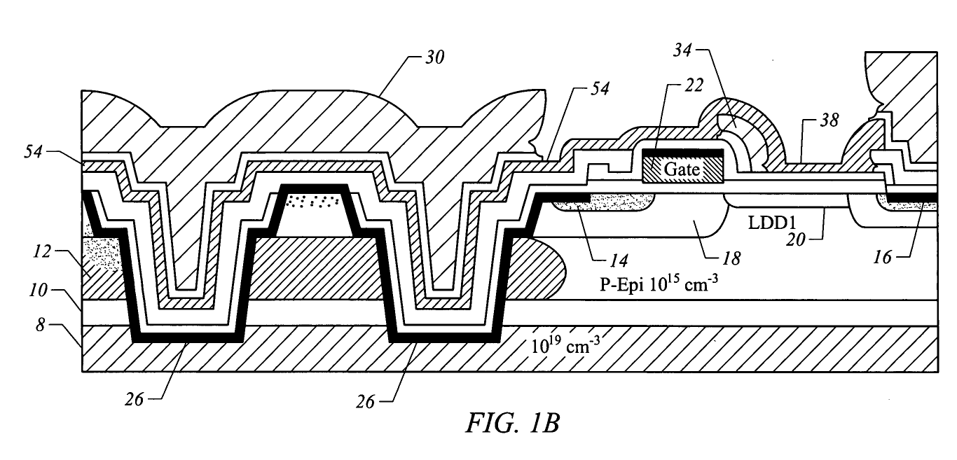

FIG. 1A is a perspective view of one embodiment of a LDMOS transistor in accordance with the invention. The transistor is fabricated on a N+ substrate 8, and an overlying P epitaxial layer 12 which includes a P+ buried layer 10. The transistor includes a N-doped source 14, and N-doped drain 16 in a surface of epitaxial layer 12 with a P-doped channel region 18 therebetween. A lightly doped drain (LDD) drain extension 20 extends from drain 16 to channel 18. A gate 22 overlies channel 18 and is spaced therefrom by a gate oxide 24.

In accordance with the invention, source 14 is ohmically connected to one plate 26 of a trench capacitor that includes top plate 30 with a dielectric layer 54 therebetween. The source capacitor allows the source to be connected to a RF ground, and gate shield 34 can be connected to the RF ground through the source capacitor by interconnecting shield 34 and top plate 30. P+ sinker 28 is not required in the trench source capacitor LDMOS, but is provided in other embodiments to ohmically connect source 14 and an extension of channel 18 to the P+ buried layer 10.

FIG. 1B is a side view in section, illustrating another embodiment of the invention in which the source capacitor comprises two or more V grooves, in epitaxial 12 and substrate 8 with the plates of the two capacitors interconnected. Thus, the total capacitance of this structure is increased by a multiple equal to the number of trenches employed. It will be noted in both embodiments that the capacitor dielectric 54 extends over the surface of gate 22 and serves as a passivation layer.

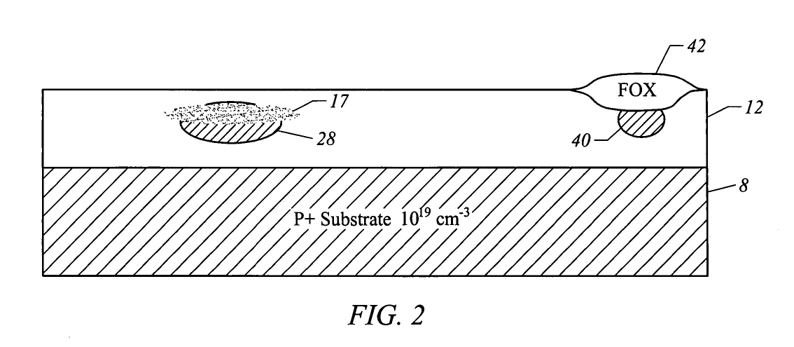

The trench capacitor structures as shown in FIGS. 1A, 1B are readily fabricated using conventional semiconductor processing techniques. FIGS. 2-22 are side views in section, illustrating steps in the fabrication of the device. In FIG. 2, the starting material is N+ silicon substrate 8 on which is grown a P-doped epitaxial layer 12 having a P buried layer 10 therein. It will be appreciated that other substrate structures such as a P-doped substrate with a P epitaxial layer grown thereon can be used without the need for a buried P+ layer. A deep P+ implant 28 is formed for the subsequent formation of a sinker and shallow doped P implant 17 formed closer to the surface for forming a P-doped surface contact. Deep P+ implant 40 is made at the same time as implant 28 and is located under field oxide 42, which together define a transistor region in epitaxial layer 12.

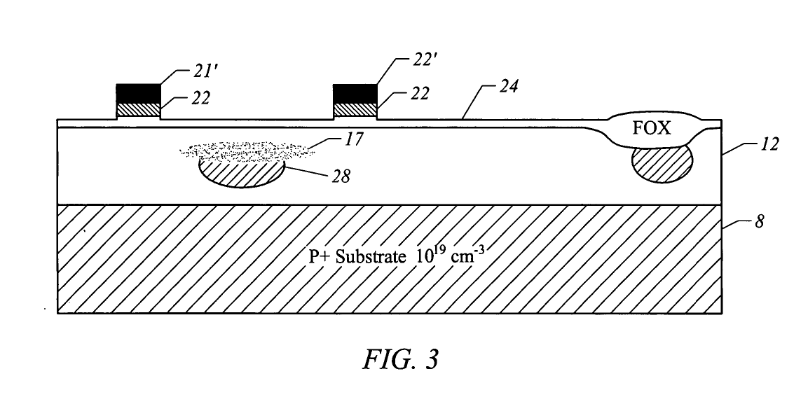

In FIG. 3, gate oxide 24 is formed on the surface of epitaxial layer 12 and gates 22 are then formed on the surface of oxide 24, spaced on either side of implants 17, 28. The gates can be a doped poly silicon and a silicide contact 22′ is formed on the surface of each gate 22.

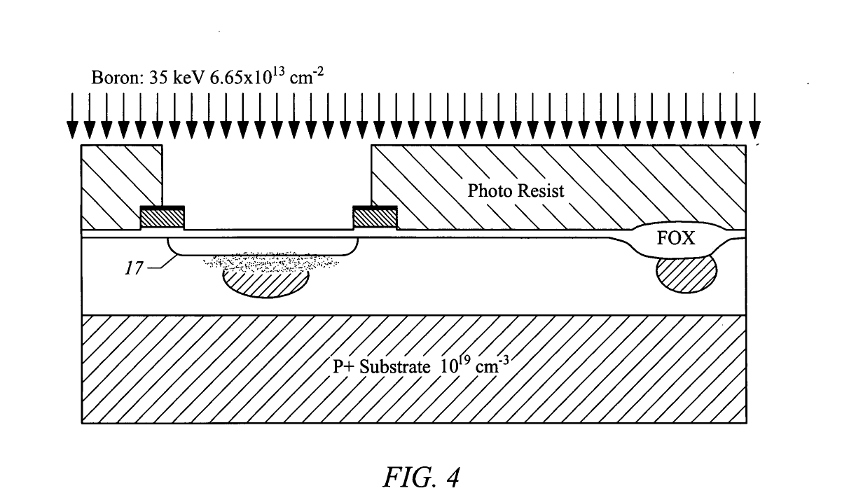

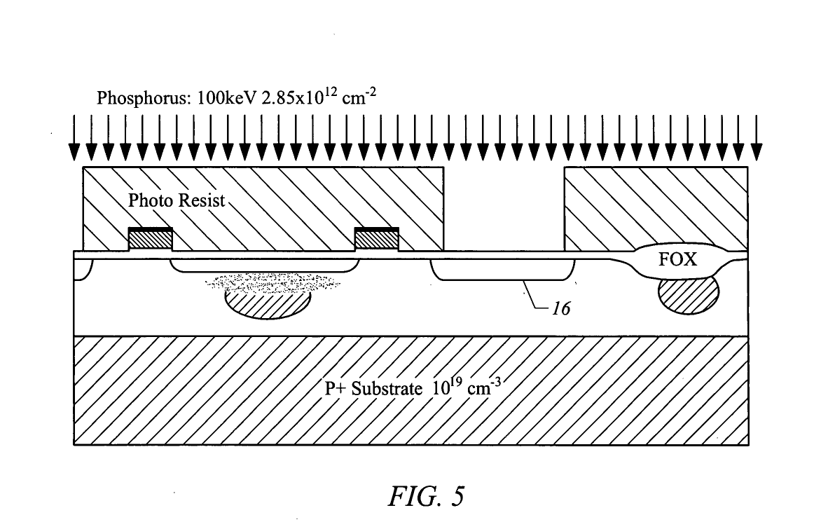

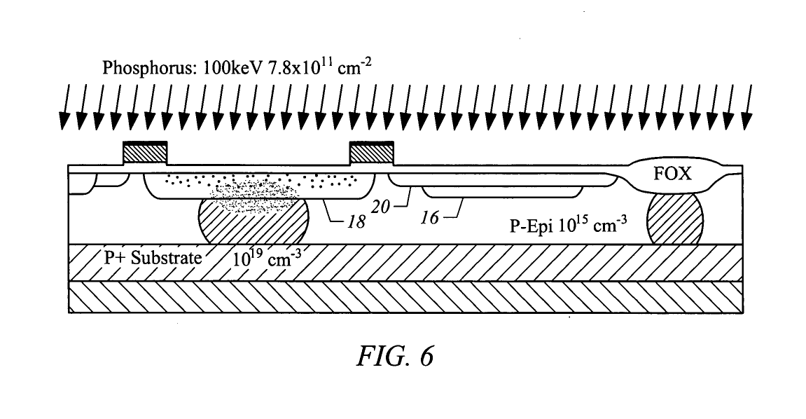

Thereafter, as shown in FIG. 4, a photoresist mask is formed on the surface of epitaxial layer 12 with a diffusion window provided between gates 22 for the implantation of boron ions for the subsequent formation of channel region 18. By using the gates 22 as part of implant mask, the implant 18 is self-aligned with the edges of the gates with the dopant ions subsequently migrating under the gates and forming channels in an thermal annealing process. In FIG. 5, a new mask is formed on the surface of epitaxial layer 12 with a diffusion window provided for implanting phosphorous and forming N-doped drain region 16. This implant can be at 100 Kev and 2.85×10¹² cm⁻² dopant concentration. Thereafter, the photoresist mask is removed and a slow ramp channel drive (1000° C. for 315 minutes) forms channel 18 under gates 22. Phosphorous is again implanted across the entire surface of epitaxial layer 12 at 100 Kev and a dosage of 7.8 10¹¹ cm⁻² as shown in FIG. 6. This implant forms the LDD extension 20 without affecting more heavily doped channel region 18.

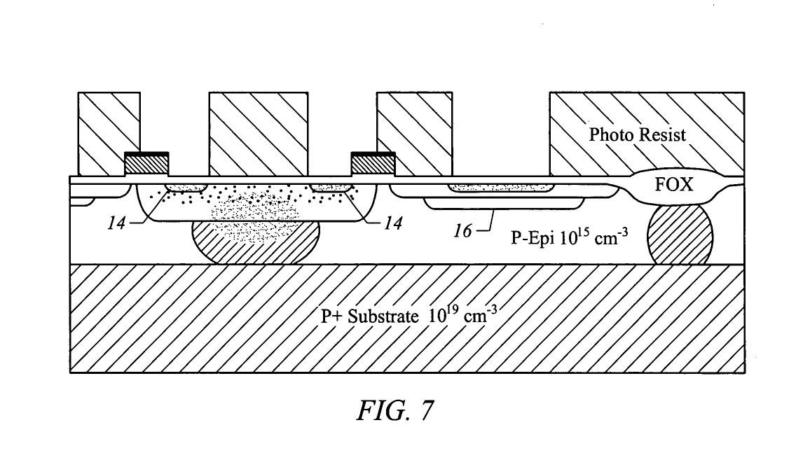

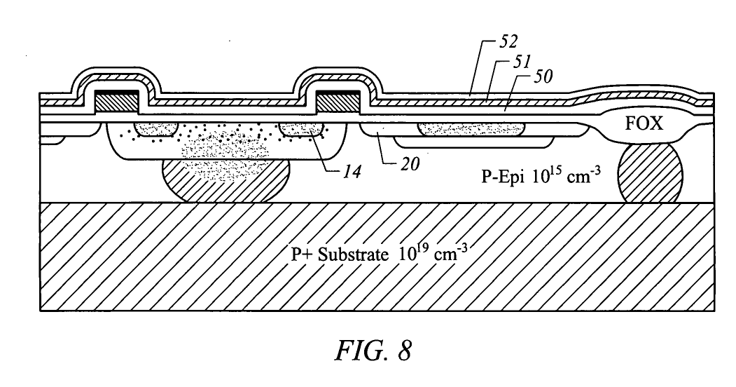

As shown in FIG. 7, a new photoresist mask is formed on the surface of the structure with windows for the implant of arsenic at 160 Kev and 7.6×10¹⁵ cm⁻² dosage for formation of N+ source regions 14 and an N+ drain region 16, as shown. The photoresist mask is then stripped and the diffusion surface cleaned. Silicon oxide layer 50, silicon nitride layer 51, and silicon oxide layer 52 are then sequentially deposited on the surface of the structure for insulation purposes, as shown in FIG. 8.

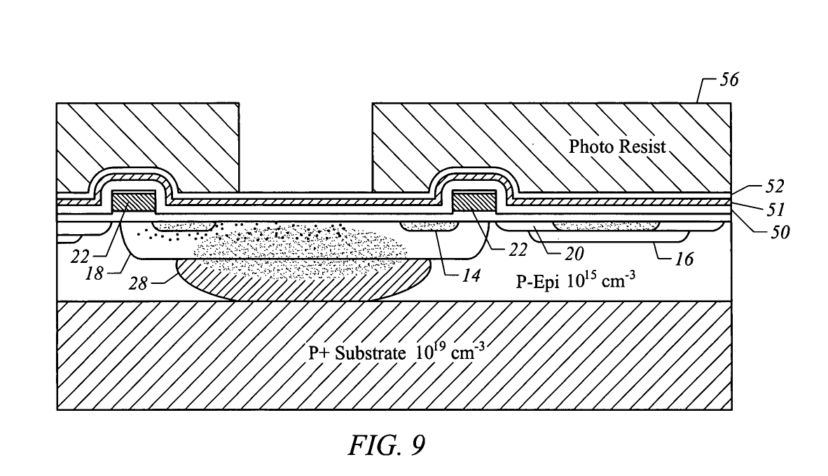

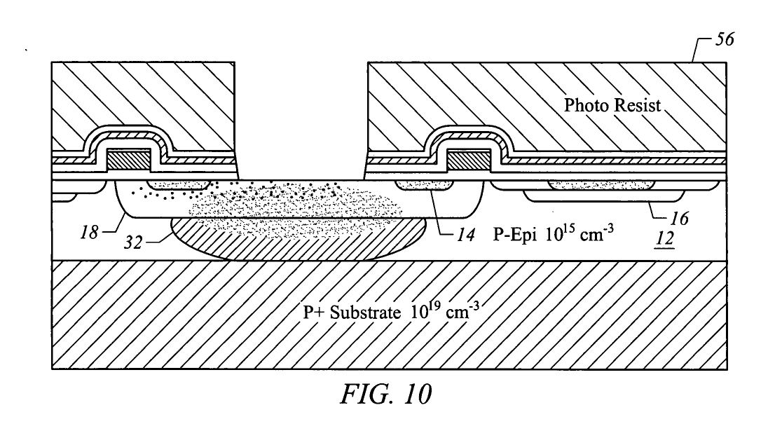

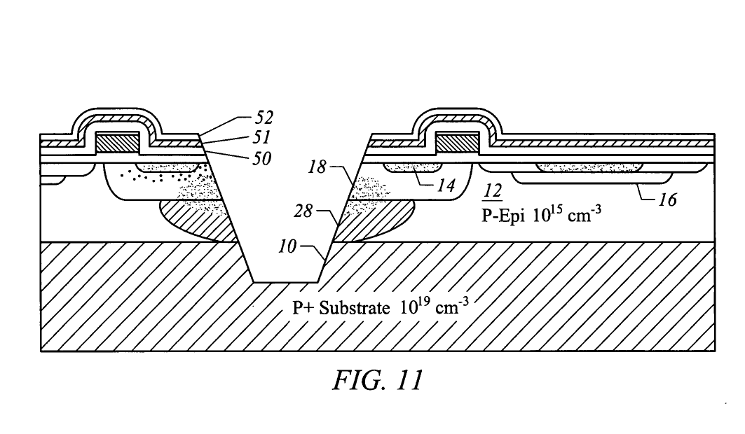

Next, the trench for the source capacitor is formed. In FIG. 9, a mask is provided over the surface with a window between gates 22, 22′. Layers 50, 51, 52 are then etched to expose the surface of epitaxial layer 12 as shown in FIG. 10, and then the silicon of the epitaxial layer and underlying substrate are etched as shown in FIG. 11. For the embodiment of FIG. 1B, two etch windows are formed between the gates for etching two trenches.

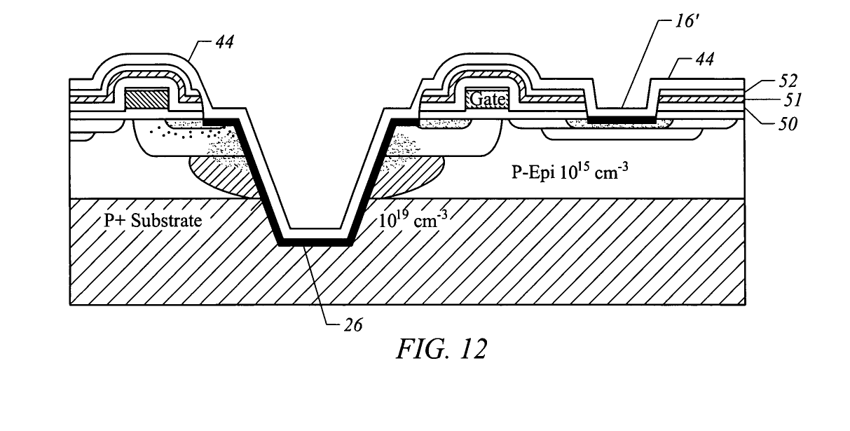

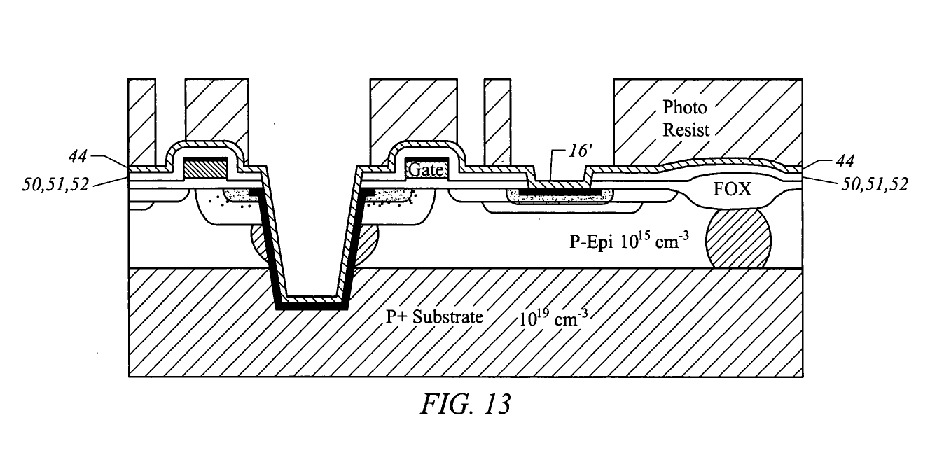

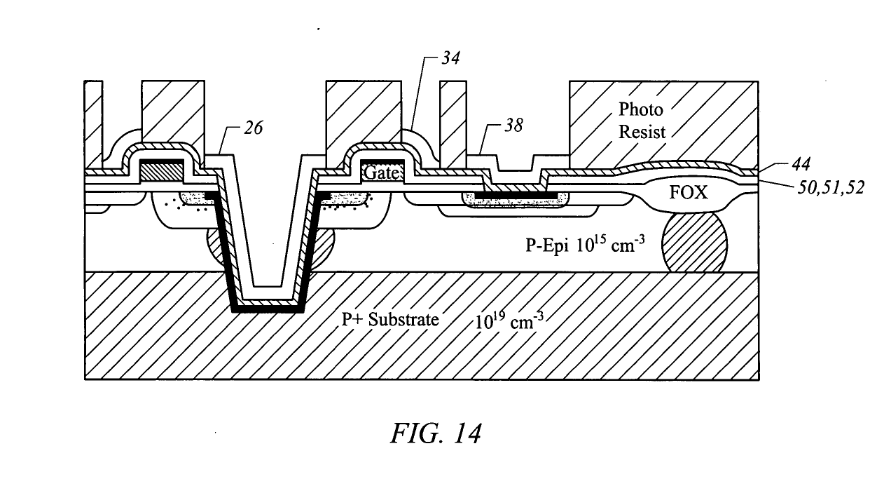

In FIG. 12 layers 50, 51 52 are removed by etching over drain 16 and then silicide capacitor plate 26 and drain contact 16′ are formed by deposition and conversion, and then a metal stack 44 of TiW, TiWN, TiW is applied over the silicide surface of the structure including the surface of trench capacitor with a thin coating of gold on the top TiW layer. Other refractory metals such as tantalum and other barrier metals for example and other high conductance metals such as copper for example can be used. Typical thickness is 2500 Å with 500 Å of gold. Next, as shown in FIG. 13, a photoresist mask is applied to the surface for the subsequent plating of gold for the first capacitor plate, shield region, and drain is shown in FIG. 14 with bottom capacitor plate 26 and metal plate 38 to drain 16, and gate shield 34. Beginning with FIG. 13, oxide layer 50, nitride layer 51, and oxide layer 52 are shown as one layer for drawing simplification.

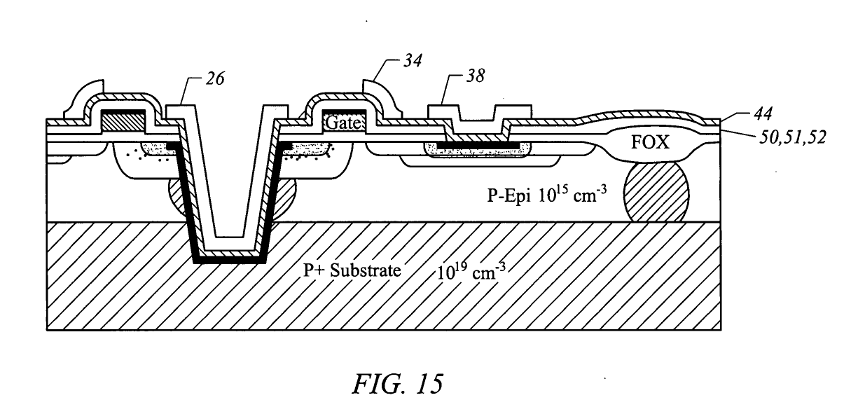

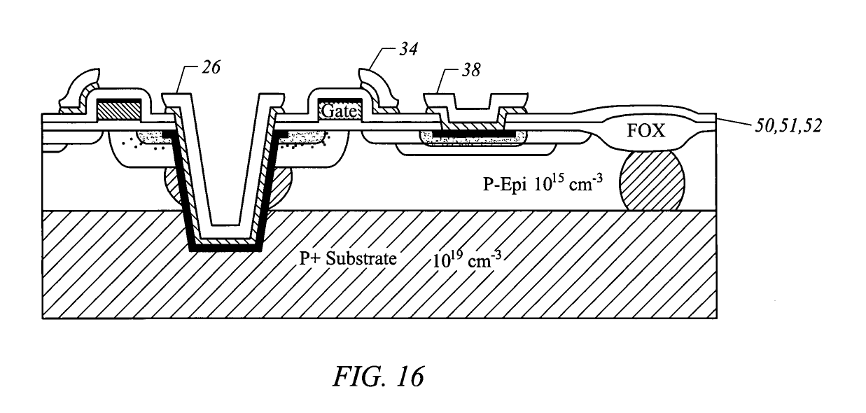

Thereafter, the photoresist is removed as shown in FIG. 15, and then the exposed thin seed layer from FIG. 12 is removed by etching along with the underlying TiW layers 44 as shown in FIG. 16. Thicker gold contacts 26, 34 and 38 are now electrically isolated from one another.

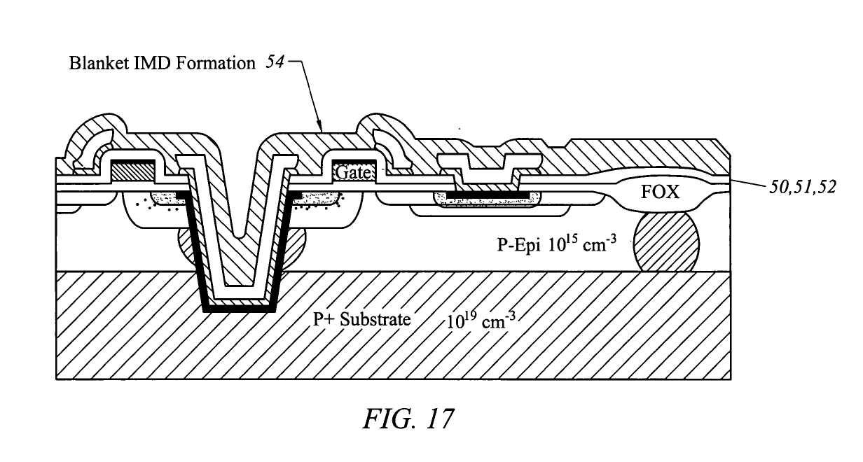

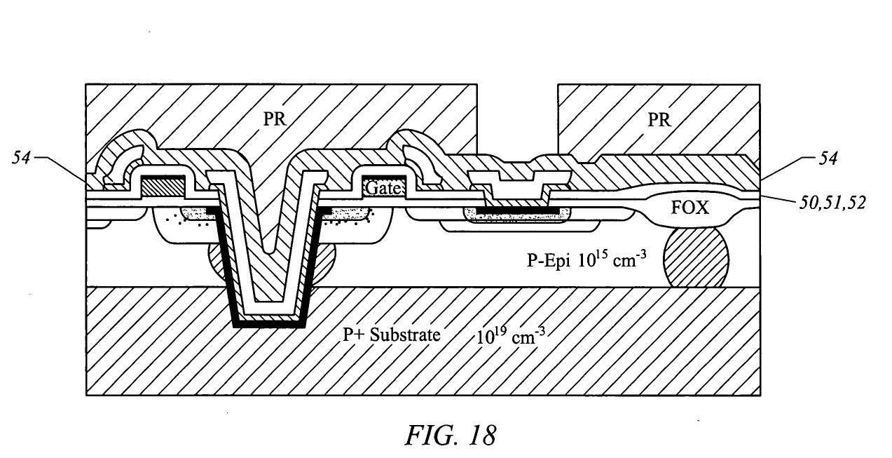

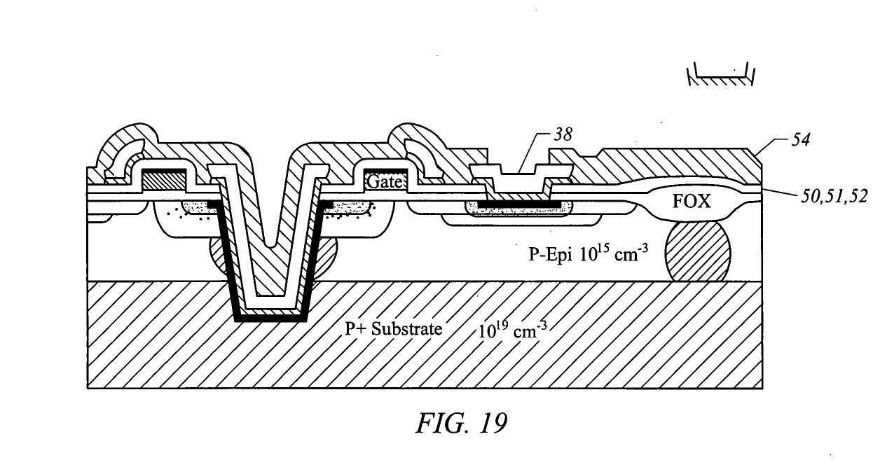

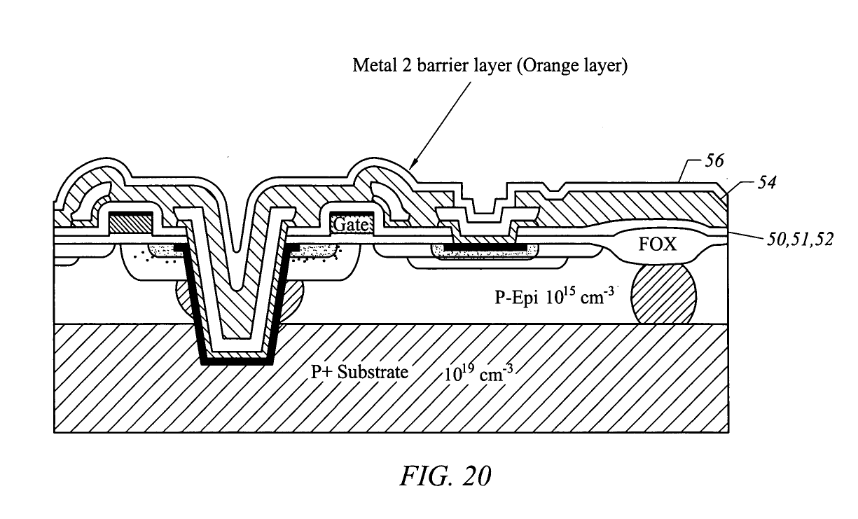

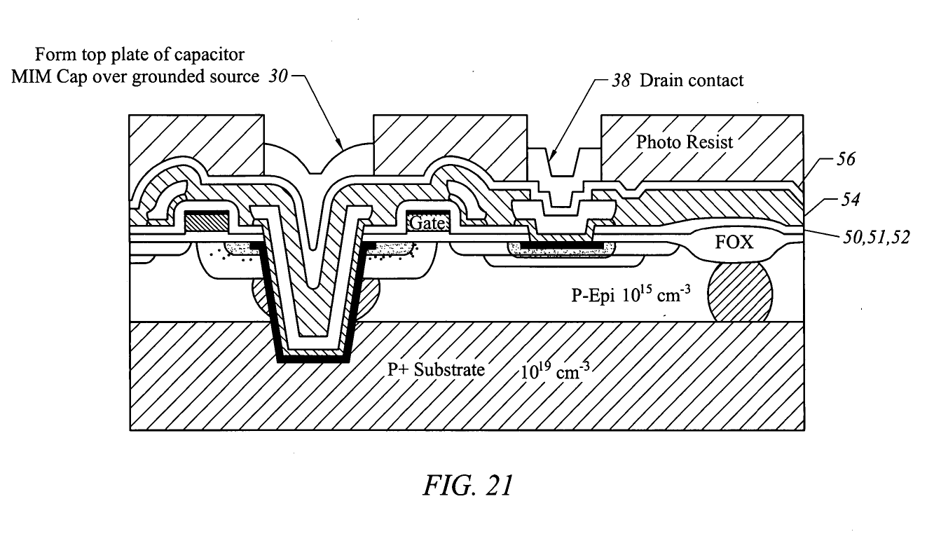

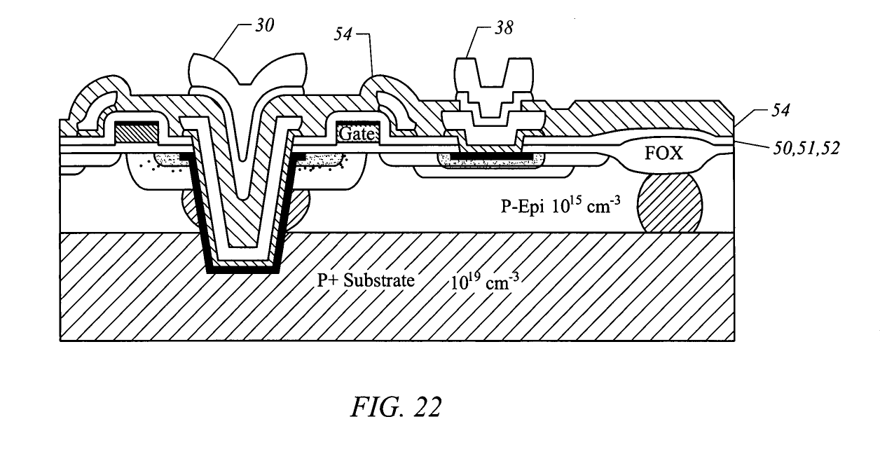

In FIG. 17, a blanket silicon nitride layer 54 is deposited and will become the source capacitor dielectric. The dielectric material can be changed in accordance with the desired capacitance since a high K dielectric (e.g. oxide, nitride, Ta0₅, HfO₂, Al₂O₃) increases capacitance whereas a low K dielectric (e.g. BPSG, Ta₂O₅, TEOS) will minimize capacitance. In FIG. 18, a photoresist mask is applied with an opening over drain contact 38 for removal of dielectric 54 as shown in FIG. 19. In this same process step, the gate and shield contact areas are also exposed (not shown in this cross section) by removal of dielectric 54. Following the removal of dielectric 54, a metal layer 56 (TiW, TiWN, TiW, gold) is formed over the surface. (FIG. 20). A photoresist mask is applied as shown in FIG. 21, and then gold is plated for the top plate 30 of the trench capacitor and for drain contact 38. The photoresist mask is then stripped as shown in FIG. 22, and then the exposed metal layer 56 is removed by etching, similar to the process in FIG. 16. At this point, the device is essentially complete.

There has been described a LDMOS transistor structure having a trench source capacitor for increased capacitance, which can be disconnected from the gate shield or interconnected with the gate shield to permit the RF grounding of the gate shield while permitting the application of a DC positive voltage bias on the shield.

While the invention has been described with reference to specific embodiments, the description is illustrative of the invention and is not to be construed as limiting the invention. Various modifications and applications may occur to those skilled in the art without departing from the true spirit and scope of the invention as defined by the appended claims.

1. A LDMOS transistor comprising:
a) a semiconductor substrate having a first major surface,
b) a source region and a drain region formed in the first major surface and spaced apart by a channel region,
c) a gate positioned over the channel region and separated therefrom by a gate dielectric layer,
d) a gate shield overlying a portion of the gate and separated therefrom by a shield dielectric layer, and
e) a source capacitor including the source region as part of one capacitor plate, a capacitor dielectric layer, and a second capacitor plate on the dielectric layer, the source capacitor formed in at least one trench in the first major surface and extending into the substrate.

2. The LDMOS transistor as defined by claim 1 wherein the substrate includes a P+ substrate and a P− epitaxial layer on the substrate, the first major surface being a surface of the P− epitaxial layer.

3. The LDMOS transistor as defined by claim 2 and further including a P-doped sinker region extending through the epitaxial layer to the P+ substrate, the one capacitor plate including a conductive layer connected to the source region and to the substrate.

4. The LDMOS transistor as defined by claim 3 and further including a metal layer on a second major surface of the substrate opposite from the first major surface, the one capacitor plate being ohmically connected to the second major surface.

5. The LDMOS transistor as defined by claim 4 wherein the conductor layer of the second capacitor plate comprises a stacked layer of TiW, TiWN, TiW, and Au.

6. The LDMOS transistor as defined by claim 4, wherein the gate shield comprises the stacked layer of TiW, TiWN, TiW, and Au.

7. The LDMOS transistor as defined by claim 6 wherein the second capacitor plate comprises a stacked layer of TiW, TiWN, TiW, and Au.

8. The LDMOS transistor as defined by claim 7 wherein the second capacitor plate and the gate shield are formed from the same stacked layer.

9. The LDMOS transistor as defined by claim 7 wherein the metal layer on the second major surface is DC grounded.

10. The LDMOS transistor as defined by claim 1 wherein the one capacitor plate is DC grounded.

11. The LDMOS transistor as defined by claim 1 wherein the source capacitor is formed in at least two adjacent trenches in the first major surface and extending into the substrate.

12. The LDMOS transistor as defined by claim 1 wherein the substrate includes a N+ substrate, and a P− epitaxial layer on the substrate with a P+ buried layer in the epitaxial layer.

13. The LDMOS transistor as defined by claim 1 and further comprising:
f) a conductor interconnecting the second capacitor plate and the gate shield.

14. The LDMOS transistor as defined by claim 1 wherein the one capacitor plate further includes a silicide layer on the source region.

15. The LDMOS transistor as defined by claim 14 wherein the one capacitor plate further including plated metal on the silicide layer.
